(19) United States
(12) Patent Application Publication
(10) Pub. No.: US 2025/0133968 A1
(43) Pub. Date: Apr. 24, 2025

(54) SPIN-ORBIT TORQUE MAGNETORESISTIVE MEMORY STRUCTURE

(71) Applicant: National Applied Research Laboratories, Taipei City (TW)

(72) Inventors: Ya-Jui Tsou, Taichung City (TW); Duan-Lee Tang, Saratoga, CA (US); Yuan-Chen Sun, Hsinchu County (TW); Kai-Shin Li, Hsinchu County (TW); Ya-Ling Wu, Hsinchu County (TW); Jia-Min Shieh, Hsinchu County (TW)

(21) Appl. No.: 18/921,034

(22) Filed: Oct. 21, 2024

(30) Foreign Application Priority Data
Oct. 24, 2023 (TW) 112140683

(51) Int. Cl. H10N 50/10; G11C 11/16; H10B 61/00; H10N 50/80

(52) U.S. Cl. CPC H10N 50/10; G11C 11/161; H10B 61/00; H10N 50/80

(57) ABSTRACT

The present invention provides a spin-orbit torque magnetoresistive memory structure, which comprises a first conductive layer, a magnetic tunneling junction (MTJ) layer, a channel layer, and a second conductive layer stacked sequentially. The MTJ layer is disposed on the first conductive layer. The channel layer is disposed on the MTJ layer. The second conductive layer is disposed on the channel layer. These structures are fabricated sequentially using lithography. By forming the MTJ layer before the channel layer, redeposition of the metal of the channel layer on the MTJ layer can be avoided.

### BACKGROUND OF THE INVENTION

With the thinner and lighter trend of various mobile devices and the demand for smart vehicles, autonomous driving, and Internet of Things (IOT) related AI, the industry is gradually developing memory that supports high-speed access, large capacity, small size, and low power consumption components. In addition to the miniaturization needs for mobile devices, wearable devices, and automotive chips, after the recent popular big-data analysis technology has gradually developed, the available cache memory at this stage no longer satisfies the computing speed required by the central processing core, and thus dragging down the efficiency of data analysis and not meeting the requirements of energy saving. Besides, the industry has developed mature static random access memory (SRAM), dynamic random access DRAM, and flash memory. Since they are approaching the development limit of size minimization and efficiency optimization, it is not easy to further respond to the demand.

In view of the above reasons, finding small size, high recording density, fast access speed, energy-saving, and nonvolatile memory is the key topic of active research and development by major technology companies and semiconductor manufacturers. Among the currently common and well-developed memory types, magnetic random access memory (MRAM) not only has the access speed and device tolerance comparable to traditional SRAM and DRAM, but also has the advantages of nonvolatility and size reduction. Thereby, it has become a new popular choice for memory research and development in recent years.

MRAM has been regarded as an important memory because of its fast access, nonvolatility, and capability of integration to current semiconductor process. MRAM has evolved from the toggle-mode type in the early time to recent spin-transfer torque (STT) type and spin-orbit torque (SOT) type. The operating mechanism changes from applying magnetic field to only a single fast pulse, and thus achieving the fast access.

However, the above-mentioned spin-orbit torque type magnetic random access memory (SOT-MRAM) is manufactured by first forming an SOT layer, and then forming the magnetic tunneling junction (MTJ) layer in the MRAM. When etching the MTJ layer, the SOT layer is redeposited on the wall surface of the MTJ layer, so that the MTJ layer is failed due to short circuit. This phenomenon is more likely to occur when the size of electronic components is further thinned and miniaturized, which further increases the manufacturing cost of a thin SOT-MRAM.

Given the above-mentioned problems according to the prior art, the present invention provides a spin-orbit torque magnetoresistive memory structure, which arranges the MTJ layer on the channel layer. The MTJ layer is formed before forming the channel layer for spin-orbit torque. Thereby, the above problems according to the prior art can be avoided.

### SUMMARY OF THE INVENTION

An objective of the present invention is to provide a spin-orbit torque magnetoresistive memory structure. The MTJ layer is disposed below the channel layer. The MTJ layer is formed before forming the channel layer for spin-orbit torque. Thereby, redeposition of the metal of the channel layer on the MTJ layer can be avoided.

To achieve the above objective and efficacy, the present invention provides a spin-orbit torque magnetoresistive memory structure, which comprises a first conductive layer, a MTJ layer, a channel layer, and a second conductive layer. The MTJ layer is disposed on the first conductive layer. The channel layer is disposed on the MTJ layer and acts as an SOT channel. The second conductive layer is disposed on the channel layer. By using this structure, redeposition of the metal of the channel layer on the MTJ layer can be avoided.

To achieve the above objective and efficacy, the present invention provides a spin-orbit torque magnetoresistive memory structure, which comprises a first conductive layer, a MTJ layer, a channel layer, and a second conductive layer. The MTJ layer is disposed on the first conductive layer. The channel layer is disposed on the MTJ layer and acts as an SOT channel. The second conductive layer is disposed below the channel layer and on the first conductive layer. By using this structure, redeposition of the metal of the channel layer on the MTJ layer can be avoided.

According to an embodiment of the present invention, the MTJ layer includes a hard layer, a tunneling layer, and a free layer. The hard layer is disposed on the first conductive layer. The tunneling layer is disposed on the hard layer. The free layer is disposed on the tunneling layer.

According to an embodiment of the present invention, the spin-orbit torque magnetoresistive memory structure further comprises a first dielectric layer covering one side of the first conductive layer.

According to an embodiment of the present invention, the spin-orbit torque magnetoresistive memory structure further comprises a passivation layer, covering one side of the MTJ layer, and disposed below the channel layer and on the first dielectric layer.

According to an embodiment of the present invention, the spin-orbit torque magnetoresistive memory structure further comprises a second dielectric layer, covering one side of the channel layer, and disposed on the passivation layer.

According to an embodiment of the present invention, the spin-orbit torque magnetoresistive memory structure further comprises a third dielectric layer, covering one side of the second conductive layer, and disposed on the second conductive layer.

According to an embodiment of the present invention, the spin-orbit torque magnetoresistive memory structure further comprises a first patterned conductive layer disposed on the second conductive layer.

According to an embodiment of the present invention, the spin-orbit torque magnetoresistive memory structure further comprises a second patterned conductive layer disposed below the first conductive layer.

According to an embodiment of the present invention, the spin-orbit torque magnetoresistive memory structure further comprises a passivation layer, covering one side of the MTJ layer and one side of the second conductive layer, and disposed below the channel layer and on the first dielectric layer.

According to an embodiment of the present invention, the spin-orbit torque magnetoresistive memory structure further comprises a second dielectric layer, disposed on the passivation layer, and covering one side of the second conductive layer.

According to an embodiment of the present invention, the spin-orbit torque magnetoresistive memory structure further comprises a third dielectric layer, covering one side of the channel layer, and disposed on the second dielectric layer

According to an embodiment of the present invention, the spin-orbit torque magnetoresistive memory structure further comprises a first patterned conductive layer disposed on the third dielectric layer.

According to an embodiment of the present invention, the spin-orbit torque magnetoresistive memory structure further comprises a second patterned conductive layer disposed below the first conductive layer.

### BRIEF DESCRIPTION OF DRAWINGS

FIG. 1 shows a schematic diagram of the structure according to the first embodiment of the present invention;

FIG. 2A to FIG. 2C show process steps according to the first embodiment of the present invention;

FIG. 3 shows a schematic diagram of patterning the conductive layer according to the first embodiment of the present invention;

FIG. 4 shows a schematic diagram of the structure according to the second embodiment of the present invention;

FIG. 5A to FIG. 5C show process steps according to the second embodiment of the present invention;

FIG. 6 shows a schematic diagram of patterning the conductive layer according to the second embodiment of the present invention; and

FIG. 7 shows a schematic diagram of another structure according to the second embodiment of the present invention.

### DETAILED DESCRIPTION OF THE INVENTION

In order to make the structure and characteristics as well as the effectiveness of the present invention to be further understood and recognized, the detailed description of the present invention is provided as follows along with embodiments and accompanying figures.

To solve the above problem according to the prior art, according to the present invention, a first conductive layer, a MTJ layer, a channel layer, and a second conductive layer are stacked. According to the design, the channel layer is disposed on the MTJ layer. In the manufacturing process, the MTJ layer is formed before forming the channel layer for avoiding redeposition of the material (such as metal) for the channel layer on the MTJ layer. According to the prior art, the redeposition problem of SOT-MRAM will lead to manufacturing difficulty and increased costs.

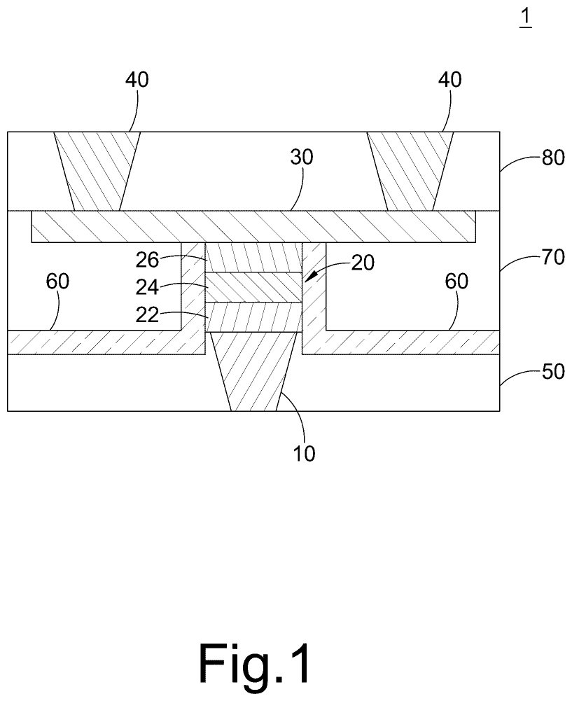

Please refer to FIG. 1, which shows a schematic diagram of the structure according to the first embodiment of the present invention. As shown in the figure, the SOT magnetoresistive memory structure 1 according to the first embodiment comprises a first conductive layer 10, a MTJ layer 20, a channel layer 30, and a second conductive layer 40 stacked sequentially from bottom up.

According to the present embodiment, the MTJ layer 20 is disposed on the first conductive layer 10. The channel layer 30 is disposed on the MTJ layer 20. The second conductive layer 40 is disposed on the channel layer 30.

According to the present embodiment, the material of the first conductive layer 10 and the material of the second conductive layer 40 are metal, which can be selected from the group consisting of, for example, tungsten (W), copper (Cu), cobalt (Co), ruthenium (Ru), titanium (Ti), and titanium nitride (TiN). Nonetheless, the present invention is not limited to the embodiment.

According to the present embodiment, the channel layer 30 is an SOT channel formed by materials including tantalum (Ta), tungsten (W), platinum (Pt), Co/Pt multilayer, or topological insulator. Nonetheless, the present invention is not limited to the embodiment.

According to the present embodiment, the thickness of the channel layer 30 is preferably between 0.1 nm and 100 nm.

Please refer to FIG. 1 again. As shown in the figure, according to the present embodiment, the MTJ layer 20 further includes a hard layer 22, a tunneling layer 24, and a free layer 26. The hard layer 22 is disposed on the first conductive layer 10/The tunneling layer 24 is disposed on the hard layer 22. The free layer 26 is disposed on the tunneling layer 24. The channel layer 30 is disposed on the free layer 26.

According to the present embodiment, the thickness of the hard layer 22 is preferably between 0.1 nm and 100 nm.

According to the present embodiment, the material of the tunneling layer 24 includes aluminum oxide (AlOₓ), magnesium oxide (MgO), and magnesium aluminum oxide (MgAl₂O₄). Nonetheless, the present invention is not limited to the embodiment.

According to the present embodiment, the thickness of the tunneling layer 24 is preferably between 0.1 nm and 50 nm.

According to the present embodiment, the material of the free layer 26 is selected from the group consisting of iron (Fe), cobalt (Co), molybdenum (Mo), tantalum (Ta), and tungsten (W). For example, it can be iron boride (FeB), cobalt iron (CoFe), and cobalt iron boride (CoFeB). Nonetheless, the present invention is not limited to the embodiment.

According to the present embodiment, the thickness of the free layer 26 is preferably between 0.1 nm and 100 nm.

According to the present embodiment, the SOT magnetoresistive memory structure 1 further comprises a first dielectric layer 50. The first dielectric layer 50 covers one side of the first conductive layer 10 and is mainly used for forming the first conductive layer 10. According to the present embodiment, the material of the first dielectric layer 50 is silicon dioxide (SiO₂) or other materials with a low dielectric constant. Nonetheless, the present invention is not limited to the embodiment.

According to the present embodiment, the SOT magnetoresistive memory structure 1 further comprises a passivation layer 60. A part of the passivation layer 60 is disposed below the channel layer 30. The other part of the passivation layer 60 is disposed on the first dielectric layer 50. According to the present embodiment, the material of the passivation layer 60 is silicon nitride (SiN). Nonetheless, the present invention is not limited to the embodiment.

According to the present embodiment, the SOT magnetoresistive memory structure 1 further comprises a second dielectric layer 70. The second dielectric layer 70 covers one side of the channel layer 30. The second dielectric layer 70 is disposed on the passivation layer 60 and is mainly used for forming the channel layer 30. According to the present embodiment, the material of the second dielectric layer 70 is silicon dioxide (SiO₂) or other materials with a low dielectric constant. Nonetheless, the present invention is not limited to the embodiment.

According to the present embodiment, the SOT magnetoresistive memory structure 1 further comprises a third dielectric layer 80. The third dielectric layer 80 covers one side of the second conductive layer 40. The third dielectric layer 80 is disposed on the second dielectric layer 70 and is mainly used for forming the second conductive layer 40. According to the present embodiment, the material of the third dielectric layer 80 is silicon dioxide (SiO₂) or other materials with a low dielectric constant. Nonetheless, the present invention is not limited to the embodiment.

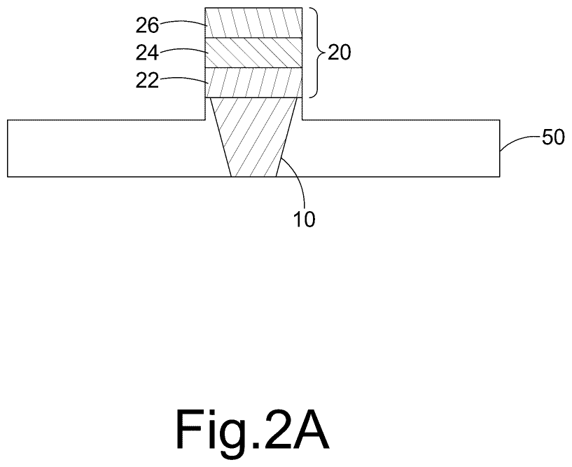

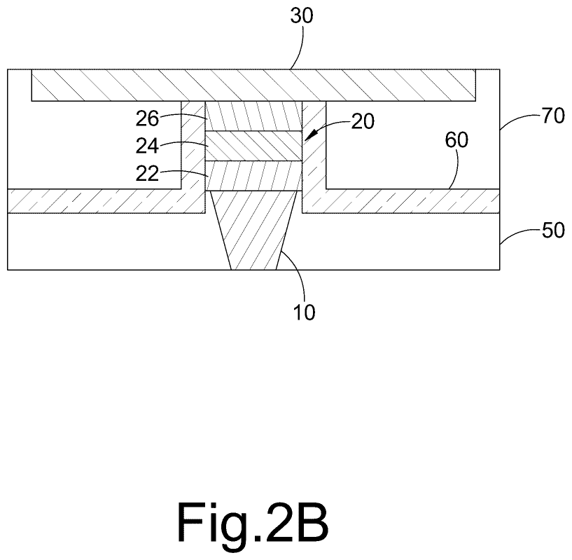

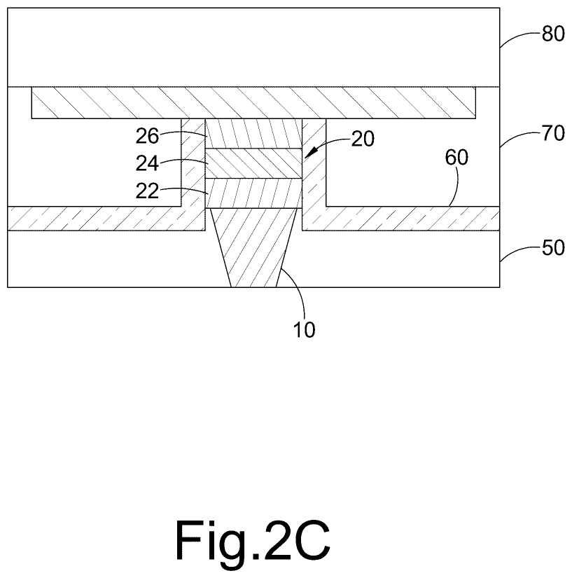

Please refer to FIG. 1 again and to FIG. 2A to FIG. 2C, which show process steps according to the first embodiment of the present invention. As shown in FIG. 2A, according to the present embodiment, form the first dielectric layer 50 first and form the first conductive layer 10 on the first dielectric layer 50. Then, form the MTJ layer 20 on the first conductive layer 10 and etch. To form the MTJ layer 20, the hard layer 22, the tunneling layer 24, and the free layer 26 are formed sequentially. As shown in FIG. 2B, form the passivation layer 60 on the first dielectric layer 50. The passivation layer 60 covers the side surface of the MTJ layer 20. Likewise, the passivation layer 60 covers the side surfaces of the hard layer 22, the tunneling layer 24, and the free layer 26. Next, form the second dielectric layer 70 on the passivation layer 60 and form the channel layer 30 on the second dielectric layer 70. As shown in FIG. 2C, form the third dielectric layer 80 on the second dielectric layer 70 and the channel layer 30. Finally, form the second conductive layer 40 on the third dielectric layer 80 to complete the structure according to the present embodiment.

According to the present embodiment, the layers can be formed by using chemical vapor deposition, atomic layer deposition (ALD), or spin coating along with lithography. Nonetheless, the present invention is not limited to the embodiment.

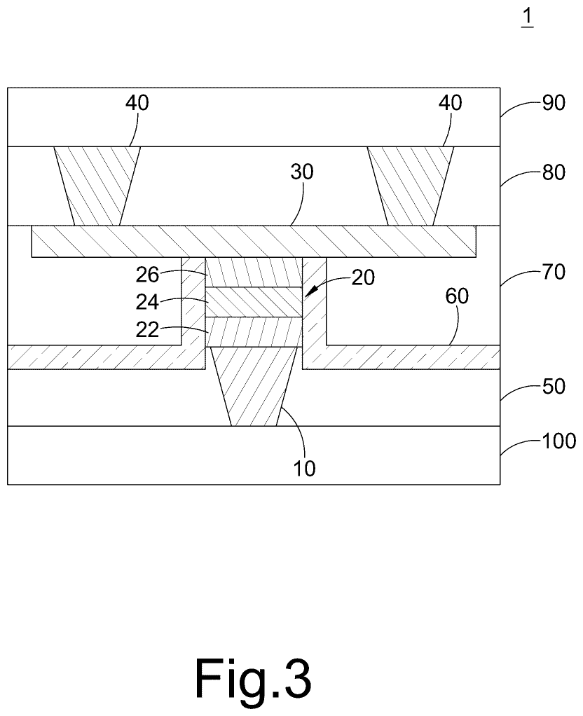

Please refer to FIG. 3, which shows a schematic diagram of patterning the conductive layer according to the first embodiment of the present invention. As shown in the figure, according to the present embodiment, the SOT magnetoresistive memory structure 1 further comprises a first patterned conductive layer 90 and a second patterned conductive layer 100. The first patterned conductive layer 90 is disposed on the second conductive layer 40 and on the third dielectric layer 80. The second patterned conductive layer 100 is disposed below the first conductive layer 10.

According to the present embodiment, after forming the second conductive layer 40, form the first patterned conductive layer 90 on the second conductive layer 40 and the third dielectric layer 80.

According to the present embodiment, the second patterned conductive layer 100 is formed before forming the first dielectric layer 50.

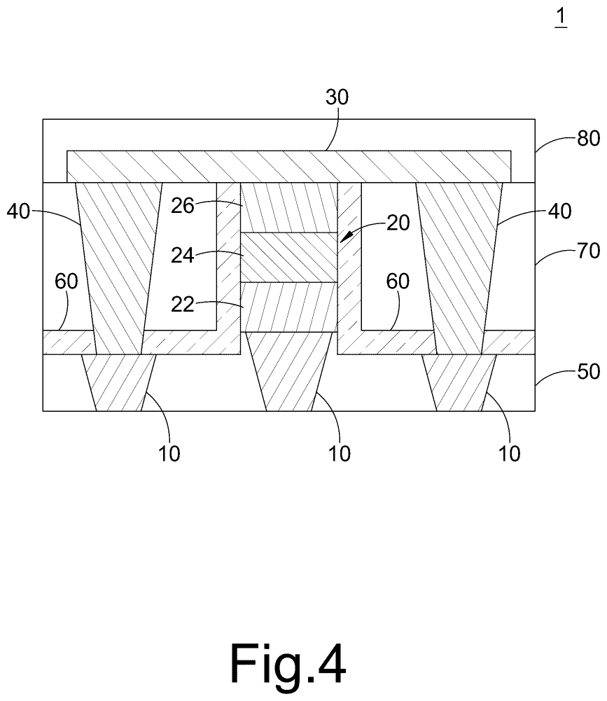

Please refer to FIG. 4, which shows a schematic diagram of the structure according to the second embodiment of the present invention. As shown in the figure, the SOT magnetoresistive memory structure 1 according to the second embodiment comprises a first conductive layer 10, a MTJ layer 20, a channel layer 30, and a second conductive layer 40 stacked sequentially from bottom up.

According to the present embodiment, the first conductive layer 10 includes a plurality of conductive bumps. The MTJ layer 20 is disposed on the first conductive layer 10. The channel layer 30 is disposed on the MTJ layer 20. The second conductive layer 40 is disposed below the channel layer 30. The second conductive layer 40 is disposed on the first conductive layer 10, so that the second conductive layer 40 is connected electrically to the channel layer 30 and the first conductive layer 10.

According to the present embodiment, the material of the first conductive layer 10 and the material of the second conductive layer 40 are metal, which can be selected from the group consisting of, for example, tungsten (W), copper (Cu), cobalt (Co), ruthenium (Ru), titanium (Ti), and titanium nitride (TiN). Nonetheless, the present invention is not limited to the embodiment.

According to the present embodiment, the channel layer 30 is an SOT channel formed by materials including tantalum (Ta), tungsten (W), platinum (Pt), Co/Pt multilayer, or topological insulator. Nonetheless, the present invention is not limited to the embodiment.

According to the present embodiment, the thickness of the channel layer 30 is preferably between 0.1 nm and 100 nm.

Please refer to FIG. 4 again. As shown in the figure, according to the present embodiment, the MTJ layer 20 further includes a hard layer 22, a tunneling layer 24, and a free layer 26. The hard layer 22 is disposed on the first conductive layer 10/The tunneling layer 24 is disposed on the hard layer 22. The free layer 26 is disposed on the tunneling layer 24. The channel layer 30 is disposed on the free layer 26.

According to the present embodiment, the thickness of the hard layer 22 is preferably between 0.1 nm and 100 nm.

According to the present embodiment, the material of the tunneling layer 24 includes aluminum oxide (AlOₓ), magnesium oxide (MgO), and magnesium aluminum oxide (MgAl₂O₄). Nonetheless, the present invention is not limited to the embodiment.

According to the present embodiment, the thickness of the tunneling layer 24 is preferably between 0.1 nm and 50 nm.

According to the present embodiment, the material of the free layer 26 is selected from the group consisting of iron (Fe), cobalt (Co), molybdenum (Mo), tantalum (Ta), and tungsten (W). For example, it can be iron boride (FeB), cobalt iron (CoFe), and cobalt iron boride (CoFeB). Nonetheless, the present invention is not limited to the embodiment.

According to the present embodiment, the thickness of the free layer 26 is preferably between 0.1 nm and 100 nm.

According to the present embodiment, the SOT magnetoresistive memory structure 1 further comprises a first dielectric layer 50. The first dielectric layer 50 covers one side of the first conductive layer 10 (including the plurality of bumps) and is mainly used for forming the first conductive layer 10. According to the present embodiment, the material of the first dielectric layer 50 is silicon dioxide (SiO₂) or other materials with a low dielectric constant. Nonetheless, the present invention is not limited to the embodiment.

According to the present embodiment, the SOT magnetoresistive memory structure 1 further comprises a passivation layer 60. A part of the passivation layer 60 is disposed below the channel layer 30. The other part of the passivation layer 60 is disposed on the first dielectric layer 50 and the first conductive layer 10. According to the present embodiment, the material of the passivation layer 60 is silicon nitride (SiN). Nonetheless, the present invention is not limited to the embodiment.

According to the present embodiment, the SOT magnetoresistive memory structure 1 further comprises a second dielectric layer 70. The second dielectric layer 70 covers one side of the second conductive layer 40. The second dielectric layer 70 is disposed on the passivation layer 60 and is mainly used for forming the second conductive layer 40. According to the present embodiment, the material of the second dielectric layer 70 is silicon dioxide (SiO₂) or other materials with a low dielectric constant. Nonetheless, the present invention is not limited to the embodiment.

According to the present embodiment, the SOT magnetoresistive memory structure 1 further comprises a third dielectric layer 80. The third dielectric layer 80 covers one side of the channel layer 30. The third dielectric layer 80 is disposed on the second dielectric layer 70 and the second conductive layer 30 and is mainly used for forming the channel layer 30. According to the present embodiment, the material of the third dielectric layer 80 is silicon dioxide (SiO₂) or other materials with a low dielectric constant. Nonetheless, the present invention is not limited to the embodiment.

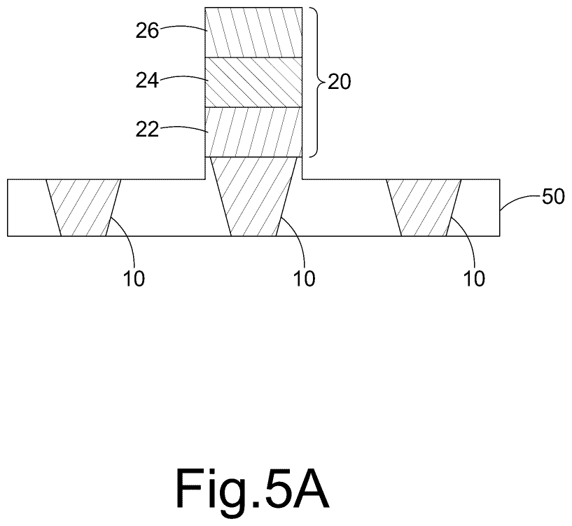

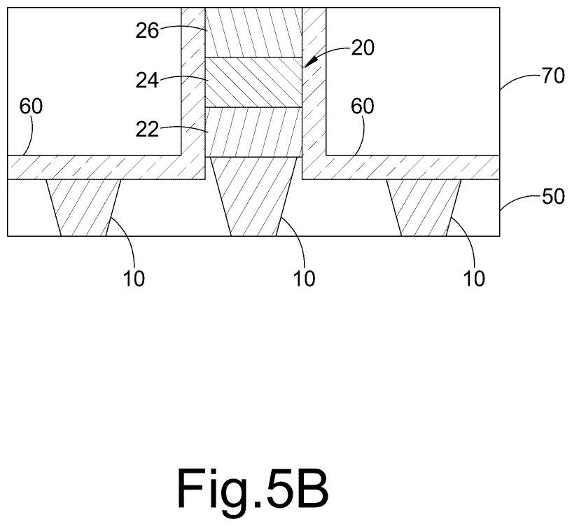

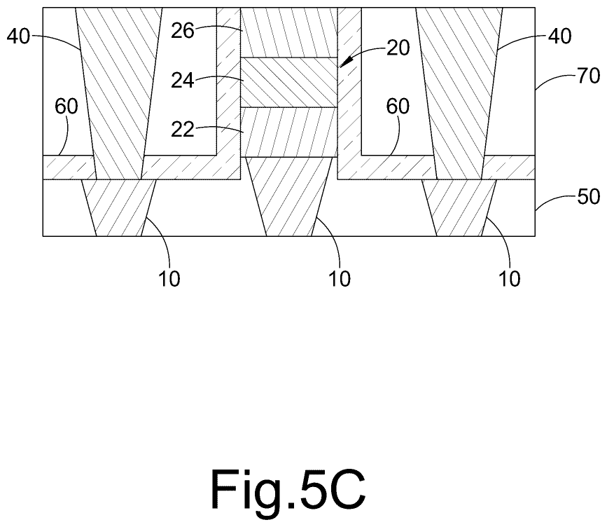

Please refer to FIG. 4 again and to FIG. 5A to FIG. 5C, which show process steps according to the second embodiment of the present invention. As shown in FIG. 5A, according to the present embodiment, form the first dielectric layer 50 first and form the first conductive layer 10 on the first dielectric layer 50. Then, form the MTJ layer 20 on the first conductive layer 10 and etch. To form the MTJ layer 20, the hard layer 22, the tunneling layer 24, and the free layer 26 are formed sequentially. As shown in FIG. 5B, form the passivation layer 60 on the first dielectric layer 50. The passivation layer 60 covers the side surface of the MTJ layer 20. Likewise, the passivation layer 60 covers the side surfaces of the hard layer 22, the tunneling layer 24, and the free layer 26. Next, form the second dielectric layer 70 on the passivation layer 60 and form the channel layer 30 on the second dielectric layer 70. As shown in FIG. 5C, form the second conductive layer 40 on the second dielectric layer 70. As shown in FIG. 4, form the third dielectric layer 80 on the second dielectric layer 70, the second conductive layer 40, and the MTJ layer 20. Finally, form the channel layer 30 on the third dielectric layer 80 to complete the structure according to the present embodiment.

According to the present embodiment, the layers can be formed by using chemical vapor deposition, atomic layer deposition (ALD), or spin coating along with lithography. Nonetheless, the present invention is not limited to the embodiment.

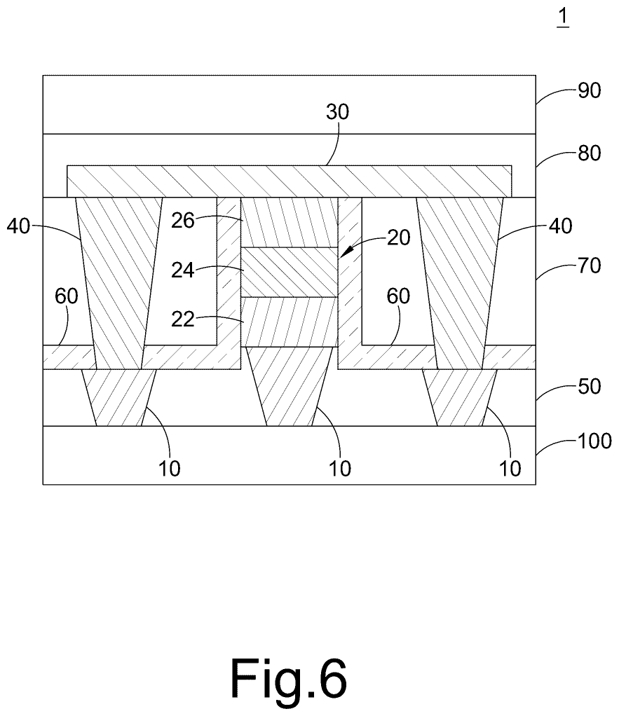

Please refer to FIG. 6, which shows a schematic diagram of patterning the conductive layer according to the second embodiment of the present invention. As shown in the figure, according to the present embodiment, the SOT magnetoresistive memory structure 1 further comprises a first patterned conductive layer 90 and a second patterned conductive layer 100. The first patterned conductive layer 90 is disposed on the third dielectric layer 80. The second patterned conductive layer 100 is disposed below the first conductive layer 10.

According to the present embodiment, after forming the third dielectric layer 80, the first patterned conductive layer 90 is formed on the third dielectric layer 80.

According to the present embodiment, the second patterned conductive layer 100 is formed before forming the first dielectric layer 50.

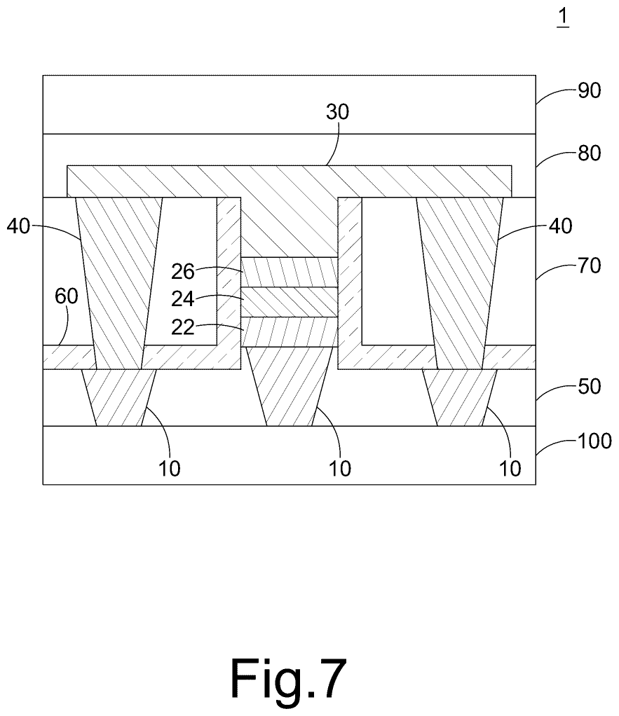

Please refer to FIG. 7, which shows a schematic diagram of another structure according to the second embodiment of the present invention. As shown in the figure, according to the present embodiment, the channel layer 30 can be further formed between the passivation layer 60.

To sum up, the present invention provides a spin-orbit torque magnetoresistive memory structure. The MTJ layer is disposed below the channel layer. The MTJ layer is formed before forming the channel layer for spin-orbit torque. Thereby, redeposition of the metal of the channel layer on the MTJ layer can be avoided. According to the prior art, the redeposition problem of SOT-MRAM will lead to manufacturing difficulty and increased costs.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

1. A spin-orbit torque magnetoresistive memory structure, comprising:
a first conductive layer;
a magnetic tunneling junction layer, disposed on said first conductive layer;
a channel layer, disposed on said magnetic tunneling junction layer, and acting as a spin-orbit torque channel; and
a second conductive layer, disposed on said channel layer.

2. The spin-orbit torque magnetoresistive memory structure of claim 1, wherein said magnetic tunneling junction layer includes:
a hard layer, disposed on said first conductive layer;
a tunneling layer, disposed on said hard layer; and
a free layer, disposed on said tunneling layer.

3. The spin-orbit torque magnetoresistive memory structure of claim 1, and further comprising a first dielectric layer covering one side of said first conductive layer.

4. The spin-orbit torque magnetoresistive memory structure of claim 3, and further comprising a passivation layer, covering one side of said magnetic tunneling junction layer, and disposed below said channel layer and on said first dielectric layer.

5. The spin-orbit torque magnetoresistive memory structure of claim 4, and further comprising a second dielectric layer, covering one side of said channel layer, and disposed on said passivation layer.

6. The spin-orbit torque magnetoresistive memory structure of claim 5, and further comprising a third dielectric layer, covering one side of said second conductive layer, and disposed on said second conductive layer.

7. The spin-orbit torque magnetoresistive memory structure of claim 1, and further comprising a first patterned conductive layer disposed on said second conductive layer.

8. The spin-orbit torque magnetoresistive memory structure of claim 1, and further comprising a second patterned conductive layer disposed below said first conductive layer.

9. A spin-orbit torque magnetoresistive memory structure, comprising:
a first conductive layer;
a magnetic tunneling junction layer, disposed on said first conductive layer;
a channel layer, disposed on said magnetic tunneling junction layer, and acting as a spin-orbit torque channel; and
a second conductive layer, disposed below said channel layer and on said first conductive layer.

10. The spin-orbit torque magnetoresistive memory structure of claim 9, wherein said magnetic tunneling junction layer includes:
a hard layer, disposed on said first conductive layer;
a tunneling layer, disposed on said hard layer; and
a free layer, disposed on said tunneling layer.

11. The spin-orbit torque magnetoresistive memory structure of claim 9, and further comprising a first dielectric layer covering one side of said first conductive layer.

12. The spin-orbit torque magnetoresistive memory structure of claim 11, and further comprising a passivation layer, covering one side of said magnetic tunneling junction layer and one side of said second conductive layer, and disposed below said channel layer and on said first dielectric layer.

13. The spin-orbit torque magnetoresistive memory structure of claim 12, and further comprising a second dielectric layer, disposed on said passivation layer, and covering one side of said second conductive layer.

14. The spin-orbit torque magnetoresistive memory structure of claim 13, and further comprising a third dielectric layer, covering one side of said channel layer, and disposed on said second dielectric layer.

15. The spin-orbit torque magnetoresistive memory structure of claim 14, and further comprising a first patterned conductive layer disposed on said third dielectric layer.

16. The spin-orbit torque magnetoresistive memory structure of claim 9, and further comprising a second patterned conductive layer disposed below said first conductive layer.
